(19) United States
(12) Patent Application Publication
(10) Pub. No.: US 2015/0244951 A1
(43) Pub. Date: Aug. 27, 2015

(54) SOLID-STATE IMAGING DEVICE AND MANUFACTURING METHOD OF SOLID-STATE IMAGING DEVICE

(71) Applicant: KABUSHIKI KAISHA TOSHIBA, Tokyo (JP)

(72) Inventor: Amane OISHI, Oita Oita (JP)

(21) Appl. No.: 14/606,879

(22) Filed: Jan. 27, 2015

(30) Foreign Application Priority Data
Jan. 31, 2014 (JP) 2014-017936

(51) Int. Cl. H04N 5/361; H01L 27/146; H04N 5/351

(52) U.S. Cl. CPC H04N 5/361; H04N 5/351; H01L 27/14621; H01L 27/14645; H01L 27/14689; H01L 27/14685; H01L 27/14627

(57) ABSTRACT

A solid-state imaging device includes a semiconductor layer, an insulation film, an electrode, and a voltage application unit. In the semiconductor layer, photodiodes that photoelectrically convert incident light into an electric charge and accumulate the electric charge are disposed in a two-dimensional array. The insulation film is formed on a surface of the semiconductor layer through which the light is incident on the photodiodes. The electrode is formed on the insulation film to surround the light receiving areas of each of the photodiodes. The voltage application unit applies a predetermined voltage to the electrode.

### CROSS-REFERENCE TO RELATED APPLICATION

This application is based upon and claims the benefit of priority from Japanese Patent Application No. 2014-017936, filed Jan. 31, 2014, the entire contents of which are incorporated herein by reference.

### FIELD

Embodiments described herein relate to a solid-state imaging device and a method of manufacturing the solid-state imaging device.

### BACKGROUND

In the related art, a camera module which is provided in a digital camera, a mobile terminal having a camera function, or the like, includes a solid-state imaging device. The solid-state imaging device is provided with a plurality of photoelectric conversion devices such as transducers or photodiodes which are disposed in a two-dimensional matrix, each one corresponding to a pixel of a captured image. Each photodiode (photoelectric conversion region) photoelectrically converts incident light into an electric charge, the quantity of which is in accordance to a quantity or quanta (intensity) of light received at the individual photodiode, and accumulates a signal charge which is representative of the intensity of the luminance of each pixel.

In addition, between each photodiode, an element isolation area is provided to electrically isolate the photodiodes from each other. The element isolation area is formed by etching a deep trench isolation (DTI) region into the semiconductor substrate or wafer, or into an epitaxial layer grown thereon, using reactive ion etching (RIE).

In DTI, for example, lattice-shaped trenches (grooves) are formed to surround each photoelectric conversion region and the trench structure extends inwardly of a semiconductor layer in which the plurality of photodiodes are formed by, for example, the above mentioned reactive ion etching (RIE) method, and the surrounded element area may be further isolated by filling the trench with an insulator, such as silicon dioxide.

As a result of the etching step, a crystal defect may be generated on a surface of the trench, causing a dangling bond to be generated in the crystal layer, i.e., a defect site is present in the crystal lattice where an electron is generated regardless of the presence or the absence of light being incident on the photodiode. This electron results in so-called dark current, which is read from photodiode, which results in a white mark in the captured image.

### DESCRIPTION OF THE DRAWINGS

FIG. 1 is a block diagram illustrating a schematic configuration of a digital camera which is provided with a solid-state imaging device according to a first embodiment.

FIG. 2 is a block diagram illustrating a schematic configuration of the solid-state imaging device according to the first embodiment.

FIG. 3 is a schematic view illustrating a cross section of a pixel array according to the first embodiment.

FIG. 4 is a view illustrating a shape of an electrode when viewed from a planar view according to the first embodiment.

FIGS. 5A to 5D are schematic cross-sectional views illustrating a manufacturing process of the solid-state imaging device according to the first embodiment.

FIGS. 6A to 6C are schematic cross-sectional views illustrating the manufacturing process of the solid-state imaging device according to the first embodiment.

FIGS. 7A to 7C are schematic cross-sectional views illustrating the manufacturing process of the solid-state imaging device according to the first embodiment.

FIGS. 8A to 8C are schematic cross-sectional views illustrating a manufacturing process of a solid-state imaging device according to a second embodiment.

FIGS. 9A to 9C are schematic cross-sectional views illustrating the manufacturing process of the solid-state imaging device according to the second embodiment.

FIG. 10 is a view illustrating another shape of the electrode when viewed from a planar view according to a third embodiment.

FIG. 11 is a view illustrating a pixel array when viewed from a cross-sectional view in a case where an electrode is provided inside a color filter, according to a fourth embodiment.

### DETAILED DESCRIPTION

One embodiment of this disclosure provides a solid-state imaging device which may reduce generation of dark current, and a method of manufacturing the solid-state imaging device.

In general, according to one embodiment, a solid-state imaging device includes: a semiconductor layer; an insulation film; an electrode; and a voltage application unit. In the semiconductor layer, photodiodes (photoelectric conversion regions) that photoelectrically convert incident light into an electric charge and accumulate the electric charge are disposed in a two-dimensional array. The insulation film is formed on a surface on the semiconductor layer through which the light is incident on the photodiodes. The electrode surrounds the light receiving area of each of the photodiodes, and is located on the insulation film surface opposite to the semiconductor layer. The voltage application unit applies a predetermined voltage to the electrode.

As a result, a potential barrier is provided in an area surrounding the light receiving side of each of the photodiodes, thus electrically isolating the photodiodes (photoelectric conversion regions) from one another without the need for a trench extending inwardly of the substrate, or inwardly of an epitaxial layer, to surround and isolate each photodiode.

Hereinafter, a solid-state imaging device and a manufacturing method of the solid-state imaging device according to embodiments will be described in detail with reference to the attached drawings. In addition, this disclosure is not limited by the embodiments.

### First Embodiment

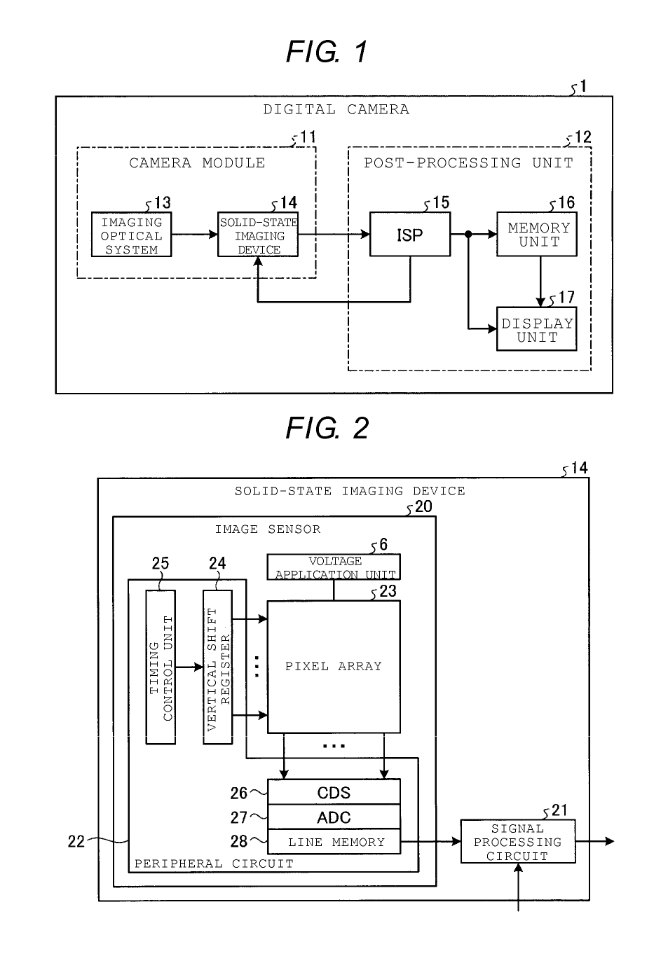

FIG. 1 is a block diagram illustrating a schematic configuration of a digital camera 1 which is provided with a solid-state imaging device 14 according to a first embodiment. As illustrated in FIG. 1, the digital camera 1 is provided with a camera module 11 and a post-processing unit 12.

The camera module 11 is provided with an imaging optical system 13 and a solid-state imaging device 14. The imaging optical system 13 receives light from a subject, and forms a subject image therewith. The solid-state imaging device 14 captures the subject image which is formed by the imaging optical system 13 and outputs an image signal, obtained by capturing, to the post-processing unit 12. The camera module 11 may be employed in an electronic apparatus, such as a mobile terminal or mobile device having a camera, in addition to the digital camera 1.

The post-processing unit 12 is provided with an image signal processor (ISP) 15, a memory unit 16, and a display unit 17. The ISP 15 performs signal processing of the image signal which is received from the solid-state imaging device 14. The ISP 15 performs image quality improvement processing, such as noise removal, pixel defect correction, or resolution modification or conversion.

The ISP 15 outputs the image signal, after the signal processing, to a signal processing circuit 21 (refer to FIG. 2) which will be described later and which is provided in the memory unit 16, the display unit 17 and the solid-state imaging device 14 of the camera module 11. The image signal which is fed back to the camera module 11 from the ISP 15 is used to adjust and control the solid-state imaging device 14.

The memory unit 16 stores the image signal input from the ISP 15 as an image. In addition, the memory unit 16 outputs the image signal of the stored image to the display unit 17 according to an operation of a user. The display unit 17 displays the image according to the image signal which is input from the ISP 15 or the memory unit 16. The display unit 17 is a liquid crystal display or the like.

Next, the solid-state imaging device 14 which is provided in the camera module 11 will be described with reference to FIG. 2. FIG. 2 is a block diagram illustrating a schematic configuration of the solid-state imaging device 14 according to the first embodiment. As illustrated in FIG. 2, the solid-state imaging device 14 is provided with an image sensor 20 and a signal processing circuit 21.

Here, a case where the image sensor 20 is a so-called rear surface irradiation type complementary metal oxide semiconductor (CMOS) image sensor in which a wiring layer is formed on or in a surface of a substrate or wafer on the opposite side of the substrate from the surface on which the light of the to be processed image is incident into the photodiode, will be described.

In addition, the image sensor 20 according to the first embodiment is not limited to the rear surface irradiation type CMOS image sensor, and may be an arbitrary image sensor, such as a front surface irradiation type CMOS image sensor or a charge coupled device (CCD) image sensor.

The image sensor 20 is provided with a peripheral circuit 22, a pixel array 23, and a voltage application unit 6. In addition, the peripheral circuit 22 is provided with a vertical shift register 24, a timing control unit 25, a correlated double sampling (CDS) system 26, an analog-digital converter (ADC) 27, and a line memory 28.

The pixel array 23 is provided in an imaging area of the image sensor 20. In the pixel array 23, a plurality of photoelectric conversion elements such as photodiodes, each one corresponding to a pixel of a captured image are disposed in a two-dimensional array (in a matrix) in a horizontal direction (row direction) and in a vertical direction (column direction). In the pixel array 23, each photodiode corresponding to each pixel generates and accumulates a signal charge (for example, an electron) according to an amount of light incident thereon.

The voltage application unit 6 applies a predetermined voltage for electrically isolating each photodiode (photoelectric conversion region) to an electrode which will be described later and which is formed on a front surface of the insulation film provided on a light receiving surface side of the photodiode in the pixel array 23.

The timing control unit 25 is a processing unit which outputs a pulse signal which establishes the operational timing with respect to the vertical shift register 24. The vertical shift register 24 is a processing unit which outputs a select signal for selecting the photodiode that reads out the signal charge, in line order, from the plurality of photodiodes disposed two-dimensionally in the pixel array 23 (matrix).

The pixel array 23 outputs the signal charge which is accumulated in each photodiode that is selected by line by the select signal input from the vertical shift register 24, to the CDS 26 from the photodiode (photoelectric conversion region) as a pixel signal which corresponds to the luminance or intensity of each pixel.

The CDS 26 is a processing unit which removes noise from the pixel signal input thereto from the pixel array 23 using correlated double sampling, and outputs the pixel signal to the ADC 27. The ADC 27 is a processing unit which converts the analog pixel signal input thereto from the CDS 26 into a digital pixel signal, and outputs the digital pixel signal to the line memory 28. The line memory 28 is a processing unit which temporarily maintains the pixel signal input from the ADC 27, and outputs the pixel signal to the signal processing circuit 21 in correspondence with each line (row or column) of the photodiode array 23.

The signal processing circuit 21 is a processing unit which performs predetermined signal processing with respect to the pixel signal input thereto from the line memory 28, and outputs the pixel signal to the post-processing unit 12. The signal processing circuit 21 performs signal processing such as lens shading correction, scratch correction, or noise reduction, with respect to the pixel signal.

In this manner, in the image sensor 20, the plurality of photodiodes disposed in the pixel array 23 photoelectrically convert the incident light into a signal charge of an amount according to a light receiving amount at the pixel, accumulates the signal charge, and performs capturing as the peripheral circuit 22 reads out the signal charge accumulated in each photodiode as the pixel signal.

In the image sensor 20, an element isolation area which electrically isolates the photodiodes (photoelectric conversion regions) from each other is required. When a trench (groove) is formed on the semiconductor layer by using reactive ion etching (RIE) to form the element isolation area, the surface of the trench may be damaged, a crystal defect is generated, and a dangling bond is generated at the defect site. An electron which is generated due to the dangling bond causes dark current. Here, in the image sensor 20, the trench formed by RIE of the semiconductor layer is not formed, and each photodiode is electrically isolated without the need for the trench.

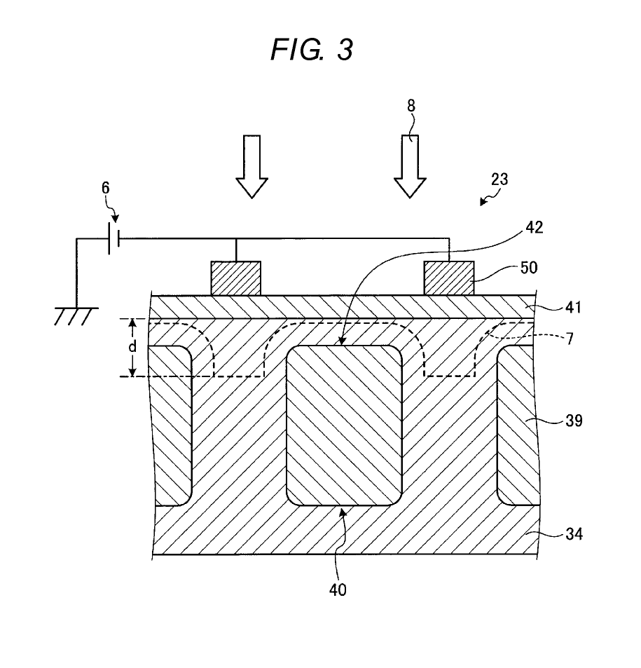

Here, a basic configuration of the pixel array 23, in which the RIE etched trench in the semiconductor layer is not formed and the adjacent photodiodes (photoelectric conversion regions) are electrically isolated from each other, will be described with reference to FIG. 3.

FIG. 3 is a schematic view illustrating a cross section of the pixel array 23 according to the first embodiment. In addition, in FIG. 3, structural elements which are necessary to describe the pixel array 23 according to the first embodiment are selectively illustrated. The detailed configuration of the pixel array 23 will be described by a manufacturing method of the solid-state imaging device 14 which includes a forming method of the pixel array 23 that will be described later.

As illustrated in FIG. 3, the pixel array 23 is provided with a first conductivity type (P-type) semiconductor (here, Si: silicon) layer 34. At a forming position of a photodiode 40 inside the P-type Si layer 34, a second conductivity type (N-type) Si area 39 is provided. In the pixel array 23, a photodiode which is formed by a PN junction between the P-type Si layer 34 and the N-type Si area 39 serves as the photodiode 40.

In addition, as illustrated in FIG. 3, on a surface on a side where light 8 is incident on the P-type Si layer 34, an insulation film 41 which is made of an insulation material having translucency is provided. On an upper surface of the insulation film 41, an electrode 50 having a light shielding property is provided. In addition, on the upper surface side of the insulation film 41, a color filter and a micro lens are provided, and the description thereof will be described later herein.

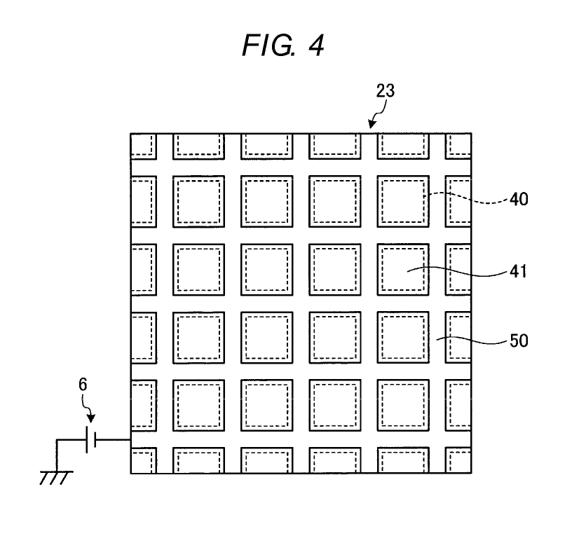

The electrode 50 is formed as a plurality of line segments, as shown in FIG. 4 a plurality of straight line segments of a conductive material, formed into a plurality of regularly repeating pattern segments, in FIG. 4 repeating squares each of which surround a light receiving area 42 on upper end surfaces of each photodiode 40. Thus, each of the repeating segments are aligned with a photodiode 40, and as discussed further herein perform a stray light shielding function with respect to adjacent photodiodes 40. In addition, the upper end surface of the photodiode 40 is on a side of the device on which light 8 is incident into the photodiode 40. In addition, the upper end surface of the photodiode 40 is the light receiving area 42 which receives the light 8 that passes through the micro lens.

In addition, the pixel array 23 is provided with the voltage application unit 6 at an arbitrary position in the image sensor 20. The voltage application unit 6 is connected to the electrode 50, and electrically isolates each photodiode 40 by applying a negative voltage to the electrode 50. Specifically, a potential barrier 7 in a well-type shape is formed in the P-type Si layer 34 at a location therein directly below the electrode 50, and thus around each photodiode 40 light receiving area 42.

The potential barrier 7 is formed between each photodiode 40 by applying a negative voltage to the electrode 50. The potential barrier 7 plays the role of preventing a negative electric charge accumulated in the photodiode 40 from flowing into an adjacent photodiode 40.

A distance d from an interface between the insulation film 41 and the P-type Si layer 34 to a bottom surface of the potential barrier 7 varies according to a quantity of the voltage applied to the electrode 50 from the voltage application unit 6. For this reason, in the pixel array 23, the voltage applied to the electrode 50 is set so that the bottom surface of the potential barrier 7 is located below the upper end surface of the photodiode 40, and thus is located between adjacent photodiodes 40 at the light receiving areas 42 thereof.

Therefore, in the pixel array 23, as the negative electric charge accumulated in the photodiodes 40 is interrupted by the potential barrier 7 formed between the adjacent photodiodes 40, the negative electric charge is not able to move to the adjacent photodiode 40 despite the lack of a trench isolation structure between the adjacent photodiodes 40.

Next, with reference to FIG. 4, a shape of the electrode 50 provided on the upper surface of the insulation film 41 will be described. FIG. 4 is a view illustrating a shape of the electrode 50 provided on the upper surface of the insulation film 41 when viewed from a planar view according to the first embodiment.

As illustrated in FIG. 4, the electrode 50 is formed in a lattice shape on the upper surface of the insulation film 41. Specifically, the electrode 50 is formed the insulation film 41 to surround each of the light receiving areas 42 on the upper end surfaces of each photodiode 40 in a rectangular (square) shape when viewed from a plan view. Light 8 which is incident on the pixel array 23 reaches the light receiving area 42 on the upper end surface of the photodiode 40 after passing through the insulation film 41 surrounded by the corresponding electrode 50.

In the pixel array 23, because the electrode 50 is formed in a lattice (repeating pattern) shape on the upper surface of the insulation film 41, the potential barrier 7 is formed in a lattice shape inwardly of the P-type Si layer 34 when the negative voltage is applied to the electrode 50. Specifically, the potential barrier 7 is formed in a depth direction from the interface between the insulation film 41 and the P-type Si layer 34 along the lower end surface of the electrode 50, and the peripheral surfaces on the upper sides of each photodiode 40 are surrounded by the potential barrier 7.

In the pixel array 23, a predetermined negative voltage is applied to the electrode 50 by the voltage application unit 6, the potential barrier 7 is formed between the adjacent photodiodes 40, and the adjacent photodiodes 40 are electrically isolated from each other by the potential barrier 7.

In this manner, in the pixel array 23, since etching which forms the trench into the P-type Si layer 34 by the RIE method is not performed, dangling bonds are not generated, and it is possible to suppress generation of the dark current caused by the crystal defect or the like.

Therefore, according to the pixel array 23, since the amount of the dark current which flows into the peripheral circuit 22 from the pixel array 23 is small, as compared to a case where the P-type Si layer 34 is etched to form an element isolation trench, it is possible to suppress generation of the problem where a white scratch appears in the captured image.

In addition, in the pixel array 23, the electrode 50 which is formed in a lattice shape on the upper surface of the insulation film 41 defines the light receiving areas 42 of each photodiode 40. For this reason, it is possible to suppress an optical color mixture which is generated as the light 8 that passes through the color filter in a diagonal direction is incident on the light receiving area 42 on the upper end surface of an adjacent photodiode 40.

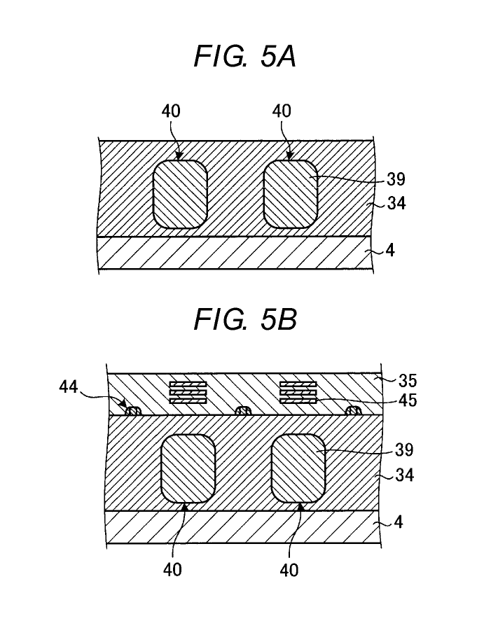

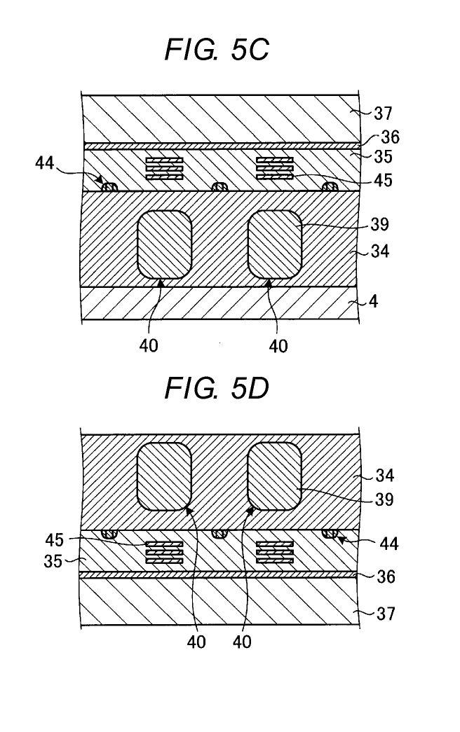

Next, the manufacturing method of the solid-state imaging device 14 which includes the method of forming the pixel array 23 will be described with reference to FIGS. 5A to 7C. In addition, a manufacturing method of portions of the solid state imaging device 14 other than the pixel array 23 is similar to that of a general CMOS image sensor. For this reason, hereinafter, only the manufacturing method of the pixel array 23 part of the solid-state imaging device 14 will be described.

FIGS. 5A to 7C are schematic cross-sectional views illustrating a manufacturing process of the solid-state imaging device 14 according to the first embodiment. As illustrated in FIG. 5A, when the pixel array 23 is manufactured, the P-type Si layer 34 is formed on a semiconductor substrate 4, such as a Silicon wafer. At this time, for example, as a silicon (Si) layer into which P-type impurities, such as boron, are doped is epitaxially grown on the semiconductor substrate 4, the P-type Si layer 34 is formed. In addition, the P-type Si layer 34 may be formed by ion implanting a p-type dopant into the silicon substrate, or into an epitaxial silicon layer formed thereon, followed by an annealing step.

Next, by ion implanting N-type impurities, such as phosphorus, into the location where the photodiode 40 will be formed in the P-type Si layer 34, followed by an annealing step to diffuse the implanted N-type dopant, N-type silicon areas are formed in a matrix, each n-type doped area 39 adjacent to and surrounded by the P-type Si layer 34. Accordingly, in the pixel array 23, at the PN junction between the P-type Si layer 34 and the N-type Si area 39, a photodiode 40 which serves as a photoelectric conversion region is formed.

Then, as illustrated in FIG. 5B, an insulation layer 35, having a reading gate 44 and a multi-layered wiring 45 embedded therein, is formed on the P-type Si layer 34. In the process, after forming the reading gate 44 or the like on the upper surface of the P-type Si layer 34, a silicon oxide layer is formed, a wiring pattern is formed on the silicon oxide layer, a metal layer such as copper or the like to form the lowermost layer of the multi-layer wiring 45 is formed, and then the silicon oxide deposition step, followed by the copper deposition step, is repeated, until the multi-layer wiring 45 is formed with a layer of silicon oxide overlying the uppermost of the wiring layers 45.

Next, as illustrated in FIG. 5C, an adhesive layer 36 is provided by coating an adhesive on the upper surface of the insulation layer 35, and a supporting substrate 37, such as a silicon wafer, is adhered to the upper surface of the adhesive layer 36. Then, the structure illustrated in FIG. 5D is flipped, and the semiconductor substrate 4 is ground away from a rear surface side (here, upper surface side) by a grinding device, such as a grinder, and the semiconductor substrate 4 is thinned to a predetermined thickness.

Then, for example, the rear surface side of the semiconductor substrate 4 is further polished by chemical mechanical polishing (CMP), and as illustrated in FIG. 5D, the rear surface (here, upper surface) which is the light receiving surface of the P-type Si layer 34 is exposed.

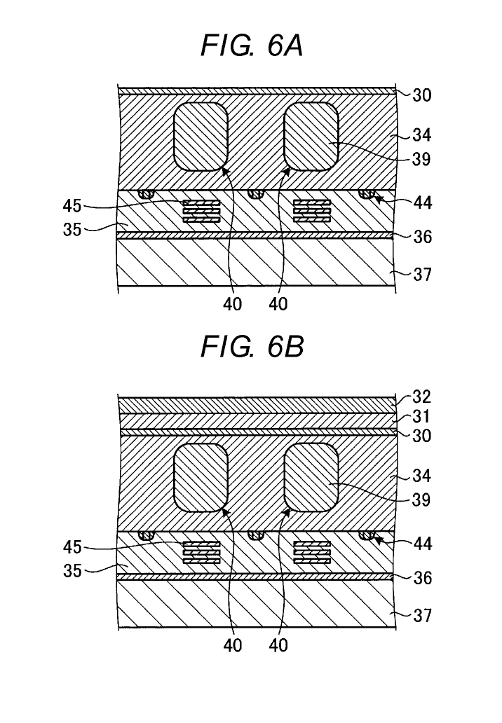

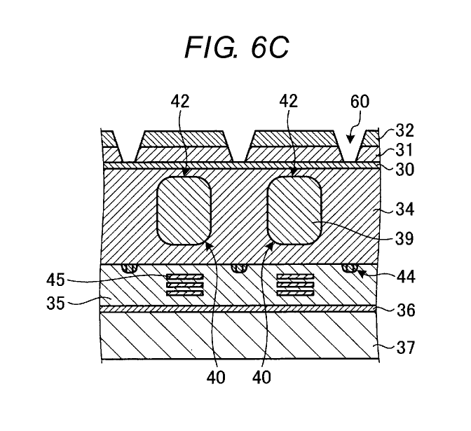

Then, as illustrated in FIG. 6A, on the upper surface of the P-type Si layer 34, for example, by using an atomic layer deposition (ALD), a fixed electric charge film 30 which is made of an insulation material, such as a hafnium oxide, is formed. The fixed electric charge film 30 maintains the negative electric charge on the layer, and a positive electric charge in the P-type Si layer 34 is accumulated on the upper surface part of the P-type Si layer 34 by the negative electric charge. Accordingly, the negative electric charge, which exists in the P-type Si layer 34 regardless of the presence or the absence of the incident light, is combined again with the positive electric charge accumulated on the upper surface part of the P-type Si layer 34, and thus, the negative electric charge is not likely to become the dark current.

Next, as illustrated in FIG. 6B, on an upper surface of the fixed electric charge film. 30, a waveguide 31 which is made of an insulation material, such as silicon nitride, and a silicon oxide insulation layer 32 which is formed from tetraethoxysilane (TEOS), are formed in this order. The waveguide 31 is an area which guides the light 8 that passes through a color filter 43 which will be described later and into the P-type Si layer 34 side. The insulation layer 32 is provided as a hardmask used during pattern etching of the waveguide 31.

On the upper surface of the insulation layer 32, for example, a resist is coated, and portions of the resist (refer to FIG. 4) corresponding to the forming position of the electrode 50 are removed by photolithographic techniques. Using the resist as a mask, for example, RIE is performed, and as illustrated in FIG. 6C, the insulation layer 32 and the waveguide 31 at the forming position of the electrode 50 are removed up to the fixed electric charge film 30, and a groove pattern 60 is formed.

In the manufacturing process according to the first embodiment, the groove pattern 60 is formed to surround the light receiving areas 42 of each photodiode 40 in a rectangular shape when viewed from a plan view of the device. In addition, the groove pattern 60 is formed so that a width of individual lines of the pattern thereof gradually narrows nearer to the upper end surface of the fixed electric charge film 30 as compared to their width at the upper end surface of the insulation layer 32.

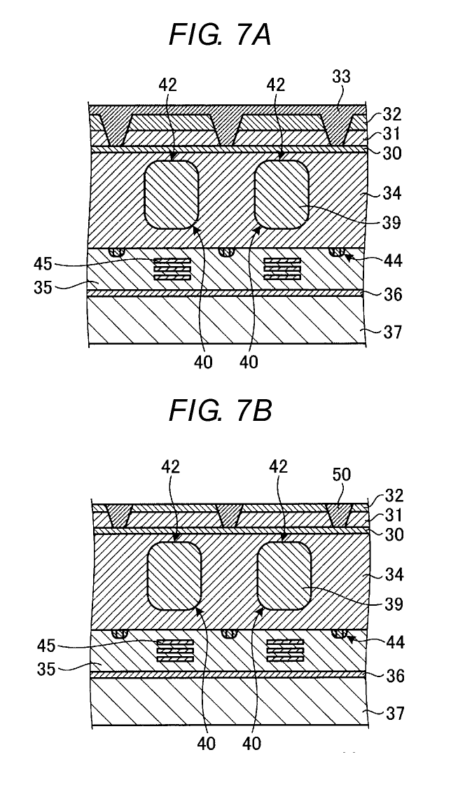

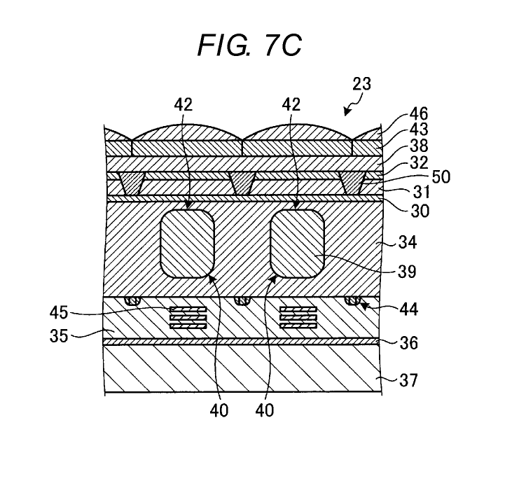

Then, the resist which is used as the mask is removed, and as illustrated in FIG. 7A, in the groove pattern 60 and the upper surface of the insulation layer 32, a conductive layer 33 which is made of a conductive material, such as a tungsten (W) is deposited, such as by a chemical vapor deposition (CVD) method.

Next, for example, the conductive layer 33 and the insulation layer 32 are removed by a polishing step, such as CMP, so that the insulation layer 32 having a predetermined thickness remains on the upper surface of the waveguide 31 by and as illustrated in FIG. 7B, embedded electrodes 50 formed of tungsten form the groove pattern 60.

In the manufacturing process according to the first embodiment, since the insulation layer 32 functions as an etch stop layer during etching of the groove pattern 60, and a polish stop layer during polishing back the tungsten not in the grooves, it is possible to prevent surface roughness of the waveguide 31 otherwise produced during CMP.

Next, the electrode 50 and the voltage application unit 6 which is installed in the image sensor 20 are connected to each other by wiring. In a configuration in which the electrode 50 and the voltage application unit 6 are connected to each other, for example, a contact hole which connects the wiring that is connected to the voltage application unit 6 among the multi-layered wirings 45 and the electrode 50 is formed on the P-type Si layer 34, and a conductive metal, such as copper, is embedded inside the contact hole.

Other than the above-described configuration, in a configuration in which the electrode 50 and the voltage application unit 6 are connected to each other, a terminal which connects the electrode 50 to the upper end surface of the insulation layer 32 may be provided, and the terminal and the voltage application unit 6 may be connected to each other by pattern wiring or the like. In addition, a disposition position of the voltage application unit 6 is an arbitrary position in the image sensor 20.

In this manner, a configuration, in which the voltage application unit 6 and the electrode 50 are connected to each other and the negative voltage is applied to the electrode 50 from the voltage application unit 6, is formed. In the pixel array 23, as the predetermined negative voltage is applied to the electrode 50, the potential barrier 7 (FIG. 3) is formed between the adjacent photodiodes 40 via the fixed electric charge film 30 which is made of the insulation material. The adjacent photodiodes 40 are electrically isolated from each other by the potential barrier 7.

As illustrated in FIG. 7C, a planarized layer 38, which has a planar surface for disposing the color filter 43 on the upper surface of the insulation layer 32, is formed. Next, color filters 43 which discriminate the wavelength of the light passing therethrough, such as the wavelengths of red, green, blue, or white light, and thus the wavelength of light penetrating to a position corresponding to the light receiving area 42 on the upper end surface of the photodiodes 40, is formed. After that, a micro lens 46 which collects and focuses the light 8 incident on the upper surface of each color filter 43 onto the photodiode 40 is formed, completing the formation of the pixel array 23.

In the pixel array 23, when the predetermined negative voltage is applied to the electrode 50 by the voltage application unit 6, the potential barrier 7 as shown in FIG. 3 is formed between the adjacent photodiodes 40, and the adjacent photodiodes 40 are then electrically isolated from each other by the potential barrier 7.

In this manner, in the pixel array 23, since etching of trenches by RIE to form an isolation region in the P-type Si layer 34 is not performed, the dangling bond is not generated, and it is possible to suppress generation of the dark current caused by the crystal defect or the like.

Therefore, according to the pixel array 23, as compared to a case where element isolation is performed by etching the P-type Si layer 34, it is possible to suppress generation of a problem in that a white scratch appears in the captured image since the amount of flow of the dark current into the peripheral circuit 22 from the pixel array 23 is small.

In addition, in the pixel array 23, the electrode 50, of which a longitudinal section shape is a V shape and which is formed in a lattice shape on the upper surface of the fixed electric charge film 30, defines the light receiving areas 42 of each photodiode 40. For this reason, it is possible to suppress light passing through, for example, a red color filter, and reaching for example, a blue, green or white light pixel region, by travelling in a diagonal direction to be incident on the light receiving area 42 on the upper end surface of the adjacent photodiode 40.

### Second Embodiment

In the above-described first embodiment, the electrode 50 is formed by embedding the conductive material inside the groove unit 60, but the manufacturing method of the electrode 50 is not limited thereto. For example, the electrode 50 may be formed by patterning the conductive layer 33.

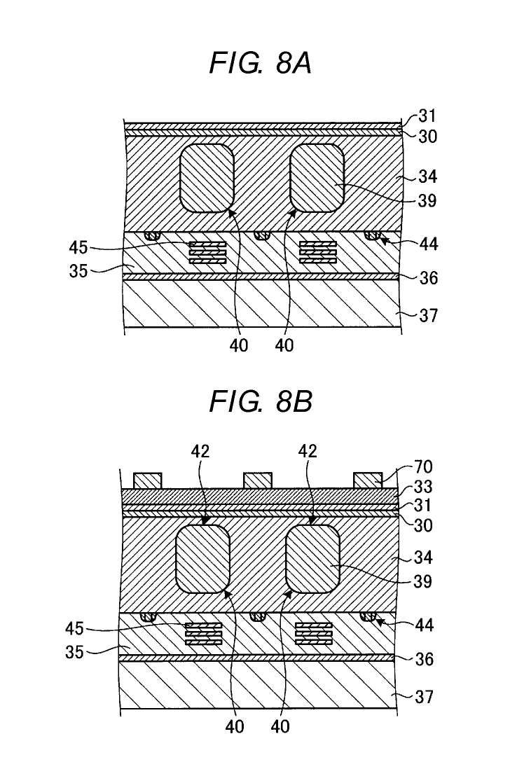

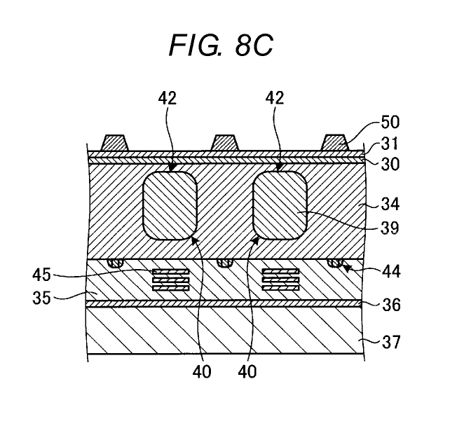

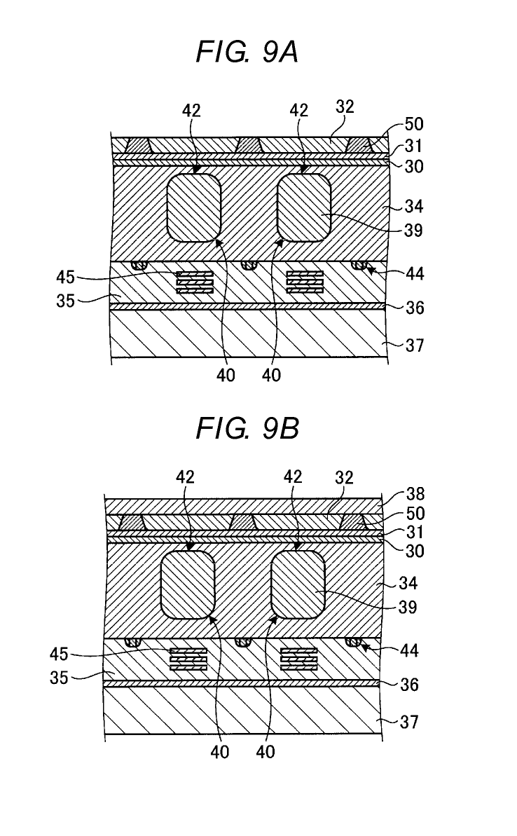

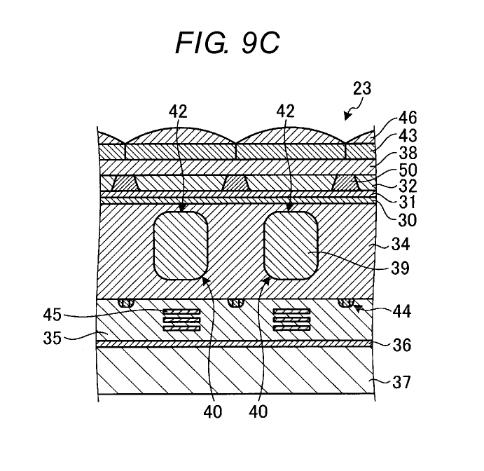

Another embodiment of the manufacturing method of the electrode 50 will be described with reference to FIGS. 8A to 9C. FIGS. 8A to 9C are schematic cross-sectional views illustrating the manufacturing process of the solid-state imaging device 14 according to a second embodiment. In addition, in the second embodiment, since the manufacturing process from FIGS. 5A to 5D described above is the same, the process will be described from forming the fixed electric charge film 30 and the waveguide 31 on the upper surface of the P-type Si layer 34.

In addition, among structural elements illustrated in FIGS. 8A to 9C, structural elements which have similar functions as the structural elements illustrated in FIG. 7C are given the same reference numerals illustrated in FIG. 7C, and detailed descriptions thereof will be omitted.

As illustrated in FIG. 8A, after exposing the rear surface (here, upper surface) which is the light receiving surface of the P-type Si layer 34, the fixed electric charge film 30 and the waveguide 31 are formed on the upper surface of the P-type Si layer 34 in this order.

Next, as illustrated in FIG. 8B, on the upper surface of the waveguide 31, the conductive layer 33 which is made of a conductive material, such as aluminum (Al), is formed by the CVD method. Then, on the upper surface of the conductive layer 33, for example, a resist 70 is coated, the resist 70 at a part (refer to FIG. 4) which is the forming position of the electrode 50 by photolithography remains, and the resist 70 other than that part is removed.

By using the resist 70 as the mask, for example, RIE of the conductive layer 33 is performed, and as illustrated in FIG. 8C, the conductive layer 33 at a part which is not covered by the resist 70 is removed, and the electrode 50 of which the longitudinal section shape is trapezoidal is formed. After that, the resist 70 which is used as the mask is removed. In the embodiment, the electrode 50 is formed to surround the light receiving areas 42 of each photodiode 40 in a rectangular shape when viewed from a plan view.

After that, as illustrated in FIG. 9A, on the upper surface of the waveguide 31, for example, a silicon oxide insulation layer 32 is formed using TEOS, and the resulting structure is polished such as by CMP to yield the structure shown in FIG. 9B. In the second embodiment, the upper end surface of the electrode 50 thus is flush with the upper end surface of the insulation layer 32, and a lateral peripheral surface of the electrode 50 is covered with the insulation layer 32.

Next, for example, a contact hole which connects the wiring that is connected to the voltage application unit 6 among the multi-layered wirings 45 and the electrode 50 is formed in the P-type Si layer 34, and a conductive metal, such as copper, is embedded inside the contact hole.

Accordingly, a configuration, in which the voltage application unit 6 and the electrode 50 are connected to each other and the negative voltage is applied to the electrode 50 from the voltage application unit 6, is formed. In the pixel array 23, as the predetermined negative voltage is applied to the electrode 50, the potential barrier 7 is formed between the adjacent photodiodes 40 via the fixed electric charge film 30 which is made of the insulation material and the waveguide 31. The adjacent photodiodes 40 are electrically isolated from each other by the potential barrier 7 as shown in FIG. 3.

Then, as illustrated in FIG. 9C, by forming the color filters 43 and the micro lenses 46 at a position which corresponds to the light receiving area 42 on the upper end surface of the photodiode 40 in this order, the pixel array 23 is formed.

In the second embodiment, since the electrode 50 is formed by patterning the conductive layer 33, there is no concern that the waveguide 31 and the insulation layer 32 get damaged by etching as in the case according to the first embodiment. Therefore, since the dangling bond is not generated in the waveguide 31 and the insulation layer 32, it is possible to further suppress generation of the dark current caused by the crystal defect.

### Third Embodiment

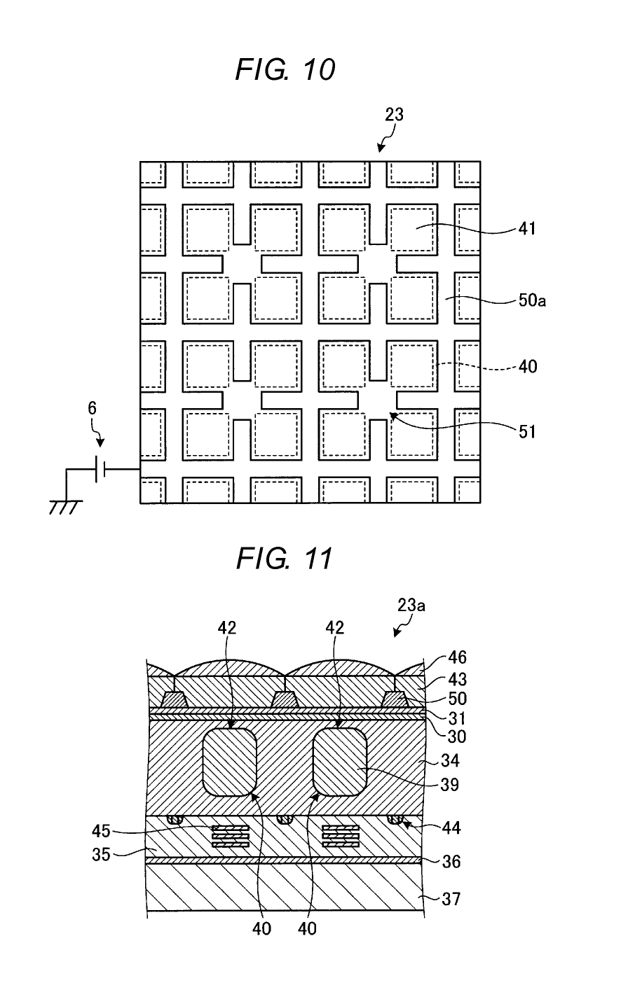

In addition, in the first and the second embodiments, as illustrated in FIG. 4, the electrode 50 is formed in a lattice shape, and continuously surrounds the light receiving area 42 on the upper end surfaces of each photodiode 40. However, the electrode 50 is not limited to the shape, and may discontinuously surround the light receiving area 42 on the upper end surfaces of each photodiode 40. With reference to FIG. 10, an electrode 50a in another shape which is provided on the upper surface of the insulation film 41 will be described. FIG. 10 is a view illustrating another shape of the electrode 50a which is provided on the upper surface of the insulation film 41 when viewed from a planar view.

As illustrated in FIG. 10, the electrode 50a is formed to surround the light receiving area 42 on the upper end surfaces of each photodiode 40 via the insulation film 41 in a C shape (an unclosed rectangle) when viewed from a planar view. When explaining in more detail, the electrode 50a surrounds the light receiving area 42 on the upper end surfaces of each photodiode 40 in a rectangular shape when viewed from a planar view, and a notch 51 which is made by notching one of four corners of the electrode 50a which surrounds the photodiode 40, is provided.

In the third embodiment, as the notch 51 is provided at least at one of the four corners of the electrode 50a which surrounds the light receiving areas 42 of each photodiode 40, when stress is created in the electrode 50a caused by differential thermal expansion of the electrode 50 and the underlying layers resulting from heat received at a time of manufacturing, it is possible to release the stress to the notch 51 provided in the electrode 50a.

Therefore, a change in shape of the electrode 50a which surrounds the light receiving area 42 on the upper end surfaces of each photodiode 40 is restrained, and it is possible to suppress reduction in light receiving areas of each photodiode 40.

In addition, in the electrode 50a which is in such a shape, the potential barrier 7 will still form even in the P-type Si layer 34 which is positioned at an end part of the electrode 50a that faces the notch unit 51. In the potential barrier 7 which is formed at each end part, since each of the end parts of the electrode 50a that faces the notch unit 51 are close to each other, the adjacent potential barriers 7 are respectively overlapped with each other.

In the third embodiment, the distance between end parts of the electrode 50a that face the notch 51 is set to make the adjacent potential barriers 7 respectively overlap with each other. Therefore, there is no concern that the negative electric charge accumulated in the photodiode 40 moves to the adjacent photodiode 40 via the notch unit 51.

### Fourth Embodiment

In addition, until here, the electrode 50 according to the first to the third embodiments is provided inside the insulation layer 32, but is not limited thereto. For example, the electrode 50 may be provided inside the color filter 43.

FIG. 11 is a view illustrating a pixel array when viewed from a cross-sectional view in a case where the color filter regions 43 are provided within the matrix or grid formed by electrode 50, according to the first to the third embodiments. In FIG. 11, apart of a schematic cross section of a pixel array 23a in the rear surface irradiation type image sensor is illustrated. In addition, among structural elements illustrated in FIG. 11, structural elements which have similar functions as the structural elements illustrated in FIG. 9C are given the same reference numerals illustrated in FIG. 9C, and detailed descriptions thereof will be omitted.

As illustrated in FIG. 11, the pixel array 23a has similar configuration to that of the 23 illustrated in FIG. 9C, except that the color filter 43 is provided on the upper surface of the waveguide 31 and the electrode 50 also having the light shielding property surrounds or substantially surrounds each of the color filters 43.

Specifically, the electrode 50 is formed on the upper surface of the waveguide 31 by patterning of a conductive layer 33 into the grid or lattice shape. The electrode 50 is thus formed to surround the light receiving area 42 on the upper end surfaces of each photodiode 40, and has openings at positions facing the light receiving area 42 on the upper end surfaces of each photodiode 40.

Each color filter 43 is formed to cover the waveguide 31 at a position corresponding to the openings of the electrode 50 and the electrode 50. In the fourth embodiment, the color filters 43 are formed to also overlie the electrode, and they abut each other in a location over the lines of the electrode 50 such that the electrode 50 is embedded at a position where the color filters 43 are in contact with each other.

In the pixel array 23a illustrated in FIG. 11, by applying the predetermined negative voltage to the electrode 50, the potential barrier 7 is formed between the adjacent photodiodes 40 via the fixed electric charge film 30 and the waveguide 31 which are made of the insulation material. With the potential barrier 7, the adjacent photodiodes 40 are electrically isolated from each other.

In addition, in the fourth embodiment, as the electrode 50 having a light shielding property is located within the color filter 43, it is possible to restrain the light 8 which is incident on the incident surface of one color filter 43 from travelling in a diagonal direction and being incident on a photoelectric conversion region (photodiode) below an adjacent color filter 43.

Furthermore, in the fourth embodiment, as the electrode 50 having a light shielding property is within the color filter 43, an installation position of the electrode 50 is close to the micro lens 46, and it is possible to more reliably shield the light which causes the optical color mixture by the electrode 50.

In addition, until here, a case where the image sensor 20 according to the first to the fourth embodiments is the rear surface irradiation type image sensor is described. However, the above-described configuration of the electrode 50 may be employed in a front surface irradiation type image sensor.

Even in this case, the adjacent photodiodes 40 may be electrically isolated from each other by the potential barrier 7 which is formed by applying the predetermined negative voltage to the electrode 50 that is similar to that in the first to the fourth embodiments, and it is possible to suppress an electric color mixture between the adjacent photodiodes 40.

In addition, in the first to the fourth embodiments, the Si layer 34 is P-type and the Si area 39 is N-type, but a pixel array 23 in which the Si layer 34 is N-type and the Si area 39 is P-type may be configured. In this case, the fixed electric charge film 30 is configured to maintain the positive electric charge. In addition, in this case, a configuration in which the positive voltage is applied to the electrode 50 from the voltage application unit 6 is employed.

In addition, the electrode 50 in the first to the fourth embodiments surrounds the light receiving area 42 on the upper end surfaces of each photodiode 40 in a rectangular shape when viewed from a planar view, but the shape is not limited thereto. For example, the electrode 50 may surround the light receiving area 42 on the upper end surfaces of each photodiode 40 in various shapes, such as a ring shape when viewed from a plan view.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device, comprising:
a semiconductor layer comprising photodiodes disposed in a two-dimensional array and configured to photoelectrically convert incident light into an electric charge and accumulate the electric charge;
an insulation film on a surface of the semiconductor layer through which light is incident on the photodiodes;
an electrode on the insulation film and surrounding the light receiving area of each of the photodiodes; and
a voltage application unit configured to apply a predetermined voltage to the electrode.

2. The device according to claim 1, further comprising:
an insulation layer on the insulation film,
wherein the electrode is disposed within the insulation layer.

3. The device according to claim 1, further comprising:
a color filter on the insulation film,
wherein the electrode is disposed within the color filter.

4. The device according to claim 1, wherein the electrode discontinuously surrounds the light receiving areas of each of the photodiodes.

5. The device according to claim 1, further comprising:
a color filter on the insulation film,
an electrode comprising a plurality of line segments forming a repeating pattern of pattern segments, wherein each pattern segment is aligned with an individual one of the photodiodes.

6. The device according to claim 5, wherein the pattern segment aligned with a photodiode shields incident light from an adjacent photodiode in the two-dimensional array.

7. The device of claim 6, wherein the line segments of the electrode are tapered.

8. A manufacturing method of a solid-state imaging device, comprising:
providing a semiconductor layer;
forming, in the semiconductor layer, a two-dimensional array of photodiodes;
forming an insulation film on a surface of the semiconductor layer through which light is incident into the photodiodes;
forming an electrode on the insulation film and having a plurality of line segments forming a pattern aligned with the light receiving areas of each of the photodiodes; and
providing a voltage application unit configured to apply a predetermined voltage to the electrode.

9. The method of claim 8, further comprising:
forming a color filter aligned to the light receiving area of a photodiode.

10. The method of claim 8, further comprising:
positioning the line segments of the electrode to block incident light into a photodiode other than the photodiode with which they are aligned.

11. The method of claim 8, further comprising:
forming a fixed charge layer between the insulating film and the semiconductor layer;
forming a hardmask layer over the insulation film;
patterning the hardmask layer and etching through the insulating film to the fixed charge layer to form trenches in the pattern of the line segments of the electrode; and
forming a conductor in the trenches.

12. The method of claim 11, further comprising:
forming a plurality of color filter layers, each color filter layer aligned with a photodiode.

13. The method of claim 12, further comprising:
forming a lens over the color filter layers.

14. The method of claim 11, wherein the trench is tapered.

15. The method of claim 11, further comprising:
filling the trench with a conductor using chemical vapor deposition, and
removing the portion of the conductor deposited on the hardmask layer using a polishing process and using the hardmask layer as an polishing stop.

16. The method of claim 8, further comprising:
forming a fixed charge layer on the semiconductor layer on the side thereof at which light is incident on the photodiodes followed by forming the insulating film on the fixed charge layer;
forming a conductive film layer on the insulating film; and
pattern etching the conductive film to forma plurality of line segments of the electrode.

17. A method of isolating individual photoelectric conversion elements in a semiconductor layer without interposing an isolation trench therebetween, wherein the photoelectric conversion elements comprise a doped semiconductor of a first conductivity type, within a semiconductor layer of a second conductivity type, comprising:
during at least a period of time when the photoelectric conversion elements are exposed to incident light, forming a potential barrier in the semiconductor layer of the second conductivity type in a location surrounding the light incident side of the photoelectric conversion elements.

18. The method of claim 17, wherein the forming of the potential barrier comprises:
providing a predetermined potential to an electrode disposed adjacent to the light incident side of the layer of the second conductivity type.

19. The method of claim 18, further comprising:
providing an insulating layer between the electrode and the layer of the second conductivity type.

20. The method of claim 17, wherein the electrode includes regularly repeating pattern segments, and at least one segment is aligned with the light incident side of a photoelectric conversion element.
